(19) United States
(12) Patent Application Publication
(10) Pub. No.: US 2007/0252732 A1
(43) Pub. Date: Nov. 1, 2007

(54) Video reproduction apparatus

(76) Inventors: Tomo Kitaguchi, Osaka (JP); Noriyuki Manabe, Osaka (JP); Katsuki Urano, Osaka (JP); Satoshi Kinoshita, Osaka (JP); Masahiro Nakamori, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/797,029

(22) Filed: Apr. 30, 2007

(30) Foreign Application Priority Data
Apr. 28, 2006 (JP) 2006-126694

(51) Int. Cl. H03M 7/00

(52) U.S. Cl. 341/50

(57) ABSTRACT

A video reproduction apparatus comprises a decoding control unit 1207 for controlling a decoding process on the basis of header information, to which an instruction for repetitive display of image is inputted; a protection processing unit for calculating a position of a coded image data stream on a coded image data stream storage buffer 1202 on the basis of a position of the coded image data stream on a decoding target input buffer 1204, which position is supplied from the decoding control unit 1207, and protecting the coded image data stream so as not to be overwritten with another coded image data stream; and a coded image data stream transfer unit 1203 for performing retransfer of the coded image data stream on the basis of the position of the coded image stream on the decoding target input buffer 1204.

### FIELD OF THE INVENTION

The present invention relates to a video reproduction apparatus and, more particularly, to a video decoding technique and a video reproduction technique to be applied to decoding and reproduction of coded video digital data which are stored in a DVD (Digital Versatile Disk), an HDD (Hard Disk Drive), or the like.

### BACKGROUND OF THE INVENTION

There are many video reproduction apparatuses for decoding and displaying coded video data streams that have been compressed according to MPEG2 or MPEG4, which apparatuses require repetitive display of the same decoded video data. For example, movie material stream reproduction, or trick play such as pause, frame-by-frame advance, or slow motion require repetitive display of the same decoded video data.

FIG. 10 is a block diagram illustrating an example of a construction of a conventional video reproduction apparatus 200 for reproducing video data based on MPEG standard.

In FIG. 10, the conventional video reproduction apparatus 200 comprises a stream analysis unit 101, a coded image data stream storage buffer 102, a coded image data stream transfer unit 103, a decoding target input buffer 104, a header detection unit 105, a decoding unit 106, a decoding control unit 107, a frame buffer 108, and a decoded image output unit 109. The processing contents of the respective constituents will be described hereinafter.

The stream analysis unit 101 analyzes a stream that is read from a DVD (Digital Versatile Disk) or an HDD (Hard Disk Drive), and stores a coded image data stream in the coded image data stream storage buffer 102.

The coded image data stream storage buffer 102 is a buffer region wherein the coded image data stream analyzed by the stream analysis unit 101 is stored.

The coded image data stream transfer unit 103 transfers the coded image data stream from the coded image data stream storage buffer 102 to the decoding target input buffer 104.

The decoding target input buffer 104 is a buffer region wherein the coded image data stream transferred by the coded image data stream transfer unit 103 is stored.

The header detection unit 105 reads the coded image data stream on the decoding target input buffer 104, detects header information, and outputs the detected header information to the decoding unit 106 and the decoding control unit 107.

The decoding unit 106 decodes the inputted coded image data stream, and stores the decoded image data stream into the frame buffer 108. The decoding unit 106 comprises a variable length decoder VLD, an inverse quantizer IQ, an inverse discrete cosine transform unit IDCT, and a motion compensation unit MC.

The decoding control unit 107 controls the decoding process performed by the decoding unit 106, and performs output setting to the decoded image output unit 109 on the basis of the header information supplied from the header detection unit 105. Further, the decoding control unit 107 receives a trick play instruction, and controls the decoding unit 106 and the decoded image output unit 109.

The frame buffer 108 is a buffer region wherein the decoded image data stream obtained in the decoding unit 106 is stored.

The decoded image output unit 109 displays the decoded image data stream stored in the frame buffer 108, on the basis of the output setting that is set by the decoding control unit 107.

Next, the operation of the conventional video reproduction apparatus 200 will be described.

First of all, a stream that is read from a DVD (Digital Versatile Disk) or an HDD (Hard Disk Drive) is analyzed by the stream analysis unit 101, and a coded image data stream included in the read stream is stored in the coded image data stream storage buffer 102. The coded image data stream stored in the coded image data stream storage buffer 102 is transferred to the decoding target input buffer 104 by the coded image data stream transfer unit 103. The coded image data stream transferred to the decoding target input buffer 104 is inputted to the header detection unit 105, wherein header information is detected. Then, the decoding control unit 107 controls the decoding unit 106 on the basis of the detected header information to perform decoding. The decoded image data stream obtained by the decoding unit 106 is stored in the frame buffer 108.

FIG. 11 is a block diagram illustrating the structure of the frame buffer 108 in the conventional image reproduction apparatus 200 shown in FIG. 10.

Decoding of an inter-frame bidirectional predictive coded picture requires prediction processes for pictures located in the forward and backward directions. Therefore, as shown in FIG. 11, in the frame buffer 108, at least three planes of regions are required, i.e., one plane for each of first and second frame buffer regions 201 and 202 (for non-inter-frame bidirectional predictive coded pictures) for storing decoded image data in both the forward and backward directions, which data are to be referred to during decoding, and one plane for a third frame buffer region 203 (for inter-frame bidirectional predictive coded pictures) for storing the result of decoding.

The decoded image data streams stored in the respective regions 201 to 203 in the frame buffer 108 are inputted to the decoded image output unit 109, and are displayed as an image according to the output setting that is set by the decoding control unit 107.

FIG. 12 shows the relationships among the decoding timing for the coded image data by the decoding unit 106, the image display timing by the decoded image output unit 109, and the decoded image data stored in the frame buffer 108.

Next, a description will be given of reproduction that requires repetitive display of the same decoded image data, in the conventional video reproduction apparatus 200.

FIG. 13 is a timing chart illustrating the relationships among the decoding process for the coded image data stream by the decoding unit 106, the decoded image data stored in the frame buffer 108, and the image display by the decoded image output unit 109, when performing reproduction of a movie material stream by the conventional image reproduction apparatus shown in FIG. 10.

The movie material stream is a stream that is composed of 24 frames/sec, like a movie film. When this stream is output to an apparatus based on a television system standard such as NTSC (60 fields/sec), since it is necessary to perform video output of 60 fields by 24 frames for every second, three-field output is performed for every other frame, as shown in FIG. 13. For example, when displaying B0, B1, I2, B3, B4, and P5 pictures, the B0 picture, the I2 picture, and the B4 picture are output by three fields while the I1 picture and the B3 picture are output by two fields.

FIG. 14 is a timing chart illustrating the relationships among the decoding process for the coded image data by the decoding unit 106, the decoded image data stored in the frame buffer 108, and the image display by the decoded image output unit 109, when performing pause playback in the conventional video reproduction apparatus 200 shown in FIG. 10.

As shown in FIG. 14, when a pause instruction is inputted, outputting of the decoded picture that is currently being outputted is continued. For example, when a pause instruction is inputted when the B picture is being outputted from the decoded image output unit 109 and displayed, outputting and display of the B0 picture are continued. When a normal playback instruction is received next, the B1 picture, the P₅ picture, . . . are subsequently decoded, and the B1 picture, the I2 picture, . . . are displayed.

FIGS. 15(a) and 15(b) are timing charts illustrating the timing of frame-by-frame advance (15(a)) and the timing of field-by-field advance (15(b)), for explaining the relationships among the decoding process for the coded image data by the decoding unit 106, the decoded image data stored in the frame buffer 108, and the image display by the decoded image output unit 109, when performing frame-by-frame (field-by-field) advance playback in the conventional video reproduction apparatus 200 shown in FIG. 10.

In the case of the frame-by-frame advance playback, as shown in FIG. 15(a), decoding is performed every time an instruction for frame-by-frame advance is inputted, whereby frame-by-frame transition is carried out. For example, when a first-time frame-by-frame advance instruction is received while the B0 picture is being displayed, decoding of the B1 picture next to the B0 picture is performed to continue display of the B1 picture. Next, when a second-time frame-by-frame advance instruction is received, next decoding (P5 picture) is performed to display the 12 picture.

On the other hand, in the case of the field-by-field advance playback, as shown in FIG. 15(b), every time an instruction for field-by-field advance is inputted, decoding and output field switching are alternately performed, whereby field-by-field transition is carried out. In any case, the same decoded image data is continuously outputted until a next field-by-field advance instruction is inputted. For example, when a first-time field-by-field advance instruction is received while the B0 picture is being displayed, decoding of the next B1 picture is carried out, and the top field of the B1 picture is continuously displayed. When a second-time field-by-field advance instruction is received, display is switched from the top field of the B1 picture to the bottom field of the B1 picture. When a third-time field-by-field advance instruction is received, next decoding (P5 picture) is carried out, and display is switched to the top field of the I2 picture.

FIG. 16 is a timing chart illustrating the relationships among the decoding process for the coded image data by the decoding unit 106, the decoded image data stored in the frame buffer 108, and the image display by the decoded image output unit 109, when performing slow-motion playback in the conventional video reproduction apparatus 200 shown in FIG. 10.

With reference to FIG. 16, when an instruction for slow motion playback is inputted, playback is carried out while outputting the same decoded image data for every designated number of times. For example, in the case of receiving a slow-motion instruction with the number of repetition times being three, when a first slow-motion instruction is received while the B0 picture is being displayed, decoding of the next B1 picture is carried out, and when second and third slow-motion instructions are received, the same B1 picture as that of the first-time instruction is decoded to continuously display the B1 picture.

As described above, the repetitive display playback by the conventional video reproduction apparatus 200 shown in FIG. 10 is carried out using the decoded image data which has once been decoded and remains on the frame buffer.

On the other hand, there is a method for realizing a video reproduction processing with a frame buffer comprising less than three planes, by reducing a region for inter-frame bidirectional predictive coded pictures, for the purpose of cost reduction and miniaturized circuit scale (refer to Japanese Published Patent Application No. 2004-343554). The inter-frame bidirectional predictive coded pictures are not referred to when decoding other coded pictures. Therefore, the frame buffer region for the inter-frame bidirectional predictive coded pictures is made less than one plane, and the data of the decoding result are stored in the region for the outputted decoded pictures.

FIG. 17 is a block diagram illustrating an example of a construction of a conventional video reproduction apparatus 300 which reproduces video data by using a frame buffer having only a region less than one plane for inter-frame bidirectional predictive coded pictures. FIG. 18 is a block diagram illustrating a structure of a frame buffer 808 included in the conventional video reproduction apparatus 300 shown in FIG. 17.

With reference to FIG. 17, the video reproduction apparatus 300 which reproduces video data with a frame buffer having only a region less than one plane for inter-frame bidirectional predictive coded pictures, comprises a stream analysis unit 801, a coded image data stream storage buffer 802, a coded image data stream transfer unit 803, a decoding target input buffer 804, a header detection unit 805, a decoding unit 806, a decoding control unit 807, a frame buffer 808, and a decoded image output unit 809. Since the constituents other than the decoding control unit 807, the frame buffer 808, and the decoded image output unit 809 are identical to those of the video reproduction apparatus 200 shown in FIG. 10, repeated description is not necessary.

The frame buffer 808 is a buffer region wherein the decoded image data stream obtained in the decoding unit 806 is stored. As shown in FIG. 18, the frame buffer 808 includes one plane for each of first and second frame buffer regions 901 and 902 for non-inter-frame bidirectional predictive coded pictures, and less than one plane for a third frame buffer region 903 for inter-frame bidirectional predictive coded pictures.

The decoding control unit 807 judges that an already-outputted decoded image data area on the third frame buffer region 903 for inter-frame bidirectional predictive coded pictures, which area is informed from the decoded image output unit 809, is writable, and notifies the decoding unit 806 of this information, when decoding the inter-frame bidirectional predictive coded pictures, in addition to the function of the conventional video reproduction apparatus 200 shown in FIG. 10.

The decoded image output unit 809 notifies the decoding control unit 807 of the already-outputted decoded image data area on the third frame buffer region 903 for inter-frame bidirectional predictive coded pictures, when decoding the inter-frame bidirectional predictive coded pictures, in addition to the function of the conventional video reproduction apparatus 200 shown in FIG. 10.

In this construction, when decoding the inter-frame bidirectional predictive coded pictures, the decoding control unit 807 and the decoded image output unit 809 cooperate with each other so as to perform writing of the decoding result while outputting the video data so that the decoded image data is not overwritten, whereby the video data can be reproduced in the video reproduction apparatus 300 including a frame buffer having only a region less than one plane for inter-frame bidirectional predictive coded pictures.

In the video reproduction apparatus 300 shown in FIG. 17 which includes a frame buffer having only a region less than one region for inter-frame bidirectional coded pictures, however, when repetitive outputting of the same inter-frame bidirectional predictive coded picture is carried out for trick play such as pause, frame-by-frame advance, slow motion, or the like, since all the decoded image data in one frame are not left in the third frame buffer region 903 for inter-frame bidirectional predictive coded pictures, it is impossible to perform video output utilizing the decoded image data in both the top and bottom fields on the frame buffer, in contrast with the conventional video reproduction apparatus 200 having the three-plane frame buffer shown in FIG. 10.

As a measure for solving this problem, it is considered that the outputted latter-half field data is not released from the frame buffer 808, and the repetitive display video is constituted by only the other field data. However, this method leads to degradation in the display video.

FIG. 19 is a timing chart illustrating the relationships among the decoding process, the frame buffer, and the decoded image output, when reproducing a movie material stream using the latter-half field data for repetitive display, in the conventional video reproduction apparatus 300 shown in FIG. 17.

With reference to FIG. 19, in the case of adopting the above-mentioned countermeasure, when displaying the B0 picture, field data of the B0 picture are decoded and outputted in order of the top field, the bottom filed, and the bottom field of the B0 picture. At this time, although all the data corresponding to one frame are not left because the third frame buffer region 903 in the frame buffer 808 is less than one plane (0.X plane), releasing of the second field (bottom field) is not performed for redisplay. Accordingly, while the third output video of the B0 picture should be originally constituted by the top field of the B0 picture, since the top field data is formed by filter processing on the basis of the bottom field data of the B0 picture that are left in the frame memory 808, the display video wobbles at constant intervals.

Further, as another countermeasure, there is considered a method of rereading data from a DVD (Digital Versatile Disk) or an HDD (Hard Disk Drive), and searching for decoded image data required for redisplay. This method is used for reverse-direction playback, and transfer in VOB units can be requested in the DVD-video standard. In this method, however, it is necessary to perform reading of data from the disk, a sequence of processes in the stream analysis unit 801 and the like, and searching for the corresponding picture, until decoding of the picture to be repeatedly displayed is performed, and therefore, a waiting time is required until video outputting.

FIG. 20 is a timing chart illustrating the relationships among the decoding process, the frame buffer, and the decoded image output, when performing filed-by-field advance playback using stream rereading from the disk, in the conventional video reproduction apparatus 300 shown in FIG. 17.

With reference to FIG. 20, when a first-time instruction for field-by-field advance is received while the B0 picture is being displayed, decoding of the next B1 picture is performed, and the top field of the B0 picture is continuously displayed. Next, when a second-time field-by-field advance instruction is received, although it is desired to switch the output field from the top field of the B1 picture to the bottom field of the B1 picture, since the third frame buffer region 903 in the frame buffer 808 is the 0.X plane, all the data corresponding to one frame are not left in the region and the bottom field of the B1 picture is absent as shown in FIG. 20, and therefore, it is necessary to reread the coded data stream from the DVD or HDD, and perform searching for the corresponding picture. As shown in FIG. 20, if request for VOB unit retransfer or searching is carried out when a field-by-field advance instruction is inputted, it is impossible to perform video output without requiring a waiting time for the instruction. That is, it results in a slow responding video reproduction apparatus.

As described above, in the conventional video reproduction apparatus, when the region for inter-frame bidirectional coded pictures in the frame buffer is reduced for cost reduction, display image is degraded, and realtime repetitive display cannot be carried out when performing trick play.

### SUMMARY OF THE INVENTION

The present invention is made to solve the above-described problems and has for its object to provide a video reproduction apparatus which can realize realtime reproduction requiring repetitive display, with no deterioration in image display, when an inter-frame bidirectional predictive coded picture is repeatedly displayed using a frame buffer having only a region less than one plate for inter-frame bidirectional predictive coded pictures.

Other objects and advantages of the invention will become apparent from the detailed description that follows. The detailed description and specific embodiments described are provided only for illustration since various additions and modifications within the scope of the invention will be apparent to those of skill in the art from the detailed description.

According to a first aspect of the present invention, there is provided a video reproduction apparatus for reproducing video data, including a frame buffer having a region less than one plane for storing inter-frame bidirectional predictive coded pictures, and the apparatus comprises: a header detection unit for detecting a header position of a coded image data stream that is stored in a decoding target input buffer; a decoding control unit for controlling a decoding process on the basis of header information supplied from the header detection unit, to which a reproduction instruction for performing repetitive display of the same decoded image data is inputted from the outside; a protection processing unit for calculating a position of the coded image data stream on the coded image data stream storage buffer, on the basis of the position of the coded image data stream on the decoding target input buffer, which is supplied from the decoding control unit, and protecting the position of the coded image data stream so as not to be overwritten with a coded image data stream different from the coded image data stream; and a coded image data stream transfer unit for, when there is a request from the decoding control unit for retransferring the coded image data stream, performing retransfer of the coded image data stream on the basis of the position of the coded image data stream on the decoding target input buffer.

According to a second aspect of the present invention, in the video reproduction apparatus according to the first aspect, the protection processing unit determines as to whether the coded image data on the coded image data stream storage buffer should be protected or not, on the basis of a coding prediction direction of the coded image data.

According to a third aspect of the present invention, in the video reproduction apparatus according to the first aspect, the decoding control unit judges as to whether retransfer of the coded image data should be performed or not, on the basis of the coding prediction direction of the coded image data, and header information that is added to the coded image data or the coded image data stream.

According to a fourth aspect of the present invention, in the video reproduction apparatus according to the first aspect, the decoding control unit judges as to whether retransfer of the coded image data should be performed or not, on the basis of the coding prediction direction of the coded image data, and a trick play instruction.

According to a fifth aspect of the present invention, in the video reproduction apparatus according to the third or fourth aspect, even when the decoding control unit determines that retransfer of the coded image data should be performed, retransfer of the coded image data is not carried out if the size of video image to be outputted is small and decoded image data to be redisplayed remains on the frame buffer.

According to a sixth aspect of the present invention, in the video reproduction apparatus according to the first aspect, when coded image data for decoding cannot be stored in the coded image data stream storage buffer, the protection processing unit does not perform protection for preventing the last-time coded image data from being overwritten, and the coded image data transfer unit transfers the coded image data next to the last-time transferred data on the coded image data stream storage buffer, to the decoding target input buffer.

### EFFECTS OF THE INVENTION

According to the video reproduction apparatus of the present invention, when an image is repeatedly displayed using a frame buffer having only a region less than one plane for inter-frame bidirectional predictive coded pictures, decoding is continuously performed, thereby realizing realtime repetitive reproduction and display having no distortion in image display, and requiring no waiting time.

According to the first aspect of the present invention, there is provided a video reproduction apparatus for reproducing video data, including a frame buffer having a region less than one plane for storing inter-frame bidirectional predictive coded pictures, and the apparatus comprises: a header detection unit for detecting a header position of a coded image data stream that is stored in a decoding target input buffer; a decoding control unit for controlling a decoding process on the basis of header information supplied from the header detection unit, to which a reproduction instruction for performing repetitive display of the same decoded image data is inputted from the outside; a protection processing unit for calculating a position of the coded image data stream on the coded image data stream storage buffer, on the basis of the position of the coded image data stream on the decoding target input buffer, which is supplied from the decoding control unit, and protecting the position of the coded image data stream so as not to be overwritten with a coded image data stream different from the coded image data stream; and a coded image data stream transfer unit for, when there is a request from the decoding control unit for retransferring the coded image data stream, performing retransfer of the coded image data stream on the basis of the position of the coded image data stream on the decoding target input buffer. The decoding control unit notifies the coded image data stream transfer unit of the head position of the coded image data on the decoding target input buffer, which head position is detected by the header detection unit, and the protection processing unit calculates, based on the information, a position of the coded image data on the coded image data stream storage buffer, and protects the coded image data so as not to be overwritten, whereby the same coded image data can be transferred again from the coded image data stream storage buffer to the decoding target input buffer, for decoding of the data to be repeatedly displayed, thereby realizing realtime reproduction requiring repetitive display, which reproduction does not lead to deterioration in image display and does not require a waiting time until video outputting, while deterioration in image display is conventionally caused by that all data corresponding to one frame are not left in the frame buffer region, and a waiting time until video outputting is conventionally caused by that the once transferred and decoded coded data stream is again read from a disk or the like.

According to the second aspect of the present invention, in the video reproduction apparatus according to the first aspect, the protection processing unit determines as to whether the coded image data on the coded image data stream storage buffer should be protected or not, on the basis of a coding prediction direction of the coded image data. Protection for preventing data from being overwritten is not performed for non-inter-frame bidirectional predictive coded pictures to which a frame buffer region enough to store all data in one frame is allocated, and new data are stored in the coded image data stream storage buffer, thereby reducing the possibility of falling into buffer under flow which causes absence of data in the coded image data stream storage buffer.

According to the third aspect of the present invention, in the video reproduction apparatus according to the first aspect, the decoding control unit judges as to whether retransfer of the coded image data should be performed or not, on the basis of the coding prediction direction of the coded image data, and header information that is added to the coded image data or the coded image data stream. Since, when performing a reproduction processing including such as frame rate conversion for a movie material stream, coded image data for repetitive display can be obtained, realtime reproduction processing including such as frame rate conversion for a movie material stream, which does not lead to deterioration in image display and does not require a waiting time until video outputting, can be realized, while deterioration in image display is conventionally caused by that all data corresponding to one frame are not left in the frame buffer region, and a waiting time until video outputting is conventionally caused by that the once transferred and decoded coded data stream is again read from a disk or the like.

According to the fourth aspect of the present invention, in the video reproduction apparatus according to the first aspect, the decoding control unit judges as to whether retransfer of the coded image data should be performed or not, on the basis of the coding prediction direction of the coded image data, and a trick play instruction. Therefore, it is possible to obtain coded image data for repetitive display which is required when performing trick play such as pause, frame-by-frame advance, or slow motion, thereby realizing trick play such as pause, frame-by-frame advance, or slow motion having no deterioration in image display, in a video reproduction apparatus including a frame buffer having only a region less than one plane for inter-frame bidirectional predictive coded pictures.

According to the fifth aspect of the present invention, in the video reproduction apparatus according to the third or fourth aspect, even when the decoding control unit determines that retransfer of the coded image data should be performed, retransfer of the coded image data is not carried out if the size of video image to be outputted is small and decoded image data to be redisplayed remains on the frame buffer. Therefore, it is possible to finally determine as to whether retransfer of the coded image data should be performed or not, by checking the frame buffer, thereby reducing the bandwidth load when the coded image data stream storage buffer is disposed on a common memory.

According to the sixth aspect of the present invention, in the video reproduction apparatus according to the first aspect, when coded image data for decoding cannot be stored in the coded image data stream storage buffer, the protection processing unit does not perform protection for preventing the last-time coded image data from being overwritten, and the coded image data transfer unit transfers the coded image data next to the last-time transferred data on the coded image data stream storage buffer, to the decoding target input buffer. Therefore, even if the coded image data exceeds an estimated size when protection processing for preventing the coded image data from being overwritten is carried out to realize retransfer, reproduction processing can be continued while the image is distorted for a moment, by canceling the protection for preventing the coded image data from being overwritten, and transferring new coded image data.

### BRIEF DESCRIPTION OF THE DRAWINGS

FIG. 1 is a block diagram illustrating a construction of a video reproduction apparatus according to a first embodiment of the present invention.

FIG. 2 is a diagram illustrating pointers of a coded image data stream storage buffer 1202 and a decoding target input buffer 1204 in the video reproduction apparatus according to the first embodiment.

FIG. 3 is a flowchart illustrating process steps to be performed by a protection processing unit 1210 in the video reproduction apparatus according to the first embodiment.

FIG. 4 is a flowchart illustrating process steps to be performed by a coded image data stream transfer unit 1203 in the video reproduction apparatus according to the first embodiment.

FIG. 5 is a flowchart illustrating process steps to be performed by a decoding control unit 1207 in the video reproduction apparatus according to the first embodiment.

FIGS. 6(a)-6(f) are diagrams illustrating transitions of pointers during video reproduction on a coded image data stream storage buffer 1202 in the video reproduction apparatus according to the first embodiment.

FIG. 7 is a diagram for explaining a method for calculating a position of a temporal guard pointer 1801, which is a position of a picture header of data on the coded image data stream storage buffer 1202 in the protection processing unit 1210 in the video reproduction apparatus according to the first embodiment.

FIG. 8 is a timing chart illustrating the relationship between a decoding process for a movie material stream and a display process thereof, in the video reproduction apparatus according to the first embodiment.

FIG. 9(a) is a flowchart of process steps to be performed by the decoding control unit 1207 in the video reproduction apparatus according to the first embodiment, illustrating a case where an inter-frame bidirectional predictive coded image is processed by trick play without performing pause.

FIG. 9(b) is a flowchart of process steps to be performed by the decoding control unit 1207 in the video reproduction apparatus according to the first embodiment, illustrating a case where an inter-frame bidirectional predictive coded image is processed by trick play with performing pause.

FIG. 9(c) is a flowchart of process steps to be performed by the decoding control unit 1207 in the video reproduction apparatus according to the first embodiment, illustrating a case where a non-inter-frame bidirectional predictive coded image is processed by trick play without performing pause.

FIG. 10 is a block diagram illustrating an example of the construction of the conventional video reproduction apparatus for reproducing MPEG based video data.

FIG. 11 is a block diagram illustrating the structure of the frame buffer 108 in the conventional video reproduction apparatus shown in FIG. 10.

FIG. 12 is a diagram illustrating the relationships among the decoding timing of the decoding unit 106, the display timing of the decoded image output unit 109, and the frame buffer 108, in the conventional image reproduction apparatus shown in FIG. 10.

FIG. 13 is a timing chart illustrating the relationships among the decoding process, the frame buffer, and the decoded image output, when reproducing a movie material stream in the conventional video reproduction apparatus shown in FIG. 10.

FIG. 14 is a timing chart illustrating the relationship among the decoding process, the frame buffer, and the decoded image output, when performing pause playback in the conventional video reproduction apparatus shown in FIG. 10.

FIGS. 15(a) and 15(b) are timing charts illustrating the relationships among the decoding process, the frame buffer and the decoded image output, when performing frame-by-frame (15(a)) and field-by-field (15(b)) advance playback is carried out in the conventional video reproduction apparatus shown in FIG. 10.

FIG. 16 is a timing chart illustrating the relationships among the decoding process, the frame buffer, and the decoded image output, when performing slow motion playback in the conventional video reproduction apparatus shown in FIG. 10.

FIG. 17 is a block diagram illustrating an example of construction of the conventional video reproduction apparatus for reproducing video data using a frame buffer having only a region less than one plane for inter-frame bidirectional predictive coded pictures.

FIG. 18 is a block diagram illustrating the structure of the frame buffer 808 in the conventional video reproduction apparatus shown in FIG. 17.

FIG. 19 is a timing chart illustrating the relationships among the decoding process, the frame buffer, and the decoded image output, when reproducing a movie material stream using the latter-half field data for repetitive display, in the conventional video reproduction apparatus shown in FIG. 17.

FIG. 20 is a timing chart illustrating the relationships among the decoding process, the frame buffer, and the decoded image output, when performing field-by-field advance playback using rereading of stream from a disk, in the conventional video reproduction apparatus shown in FIG. 17.

### DETAILED DESCRIPTION OF THE PREFERRED EMBODIMENTS

Hereinafter, an embodiment of the present invention will be described with reference to the drawings.

The embodiment of the present invention will be described for a case of processing MPEG2. Further, a decoding unit of a video reproduction apparatus used for the embodiment of the present invention requires at least 1.3 vertical scanning period for processing one frame.

### Embodiment 1

According to a first embodiment of the present invention, in a video reproduction apparatus 100 which reproduces video data using a frame buffer having only a region less than one plane for inter-frame bidirectional predictive coded pictures, the same coded image data can be again transferred from a coded image data stream storage buffer and displayed to realize repetitive display of inter-frame bidirectional predictive coded image data.

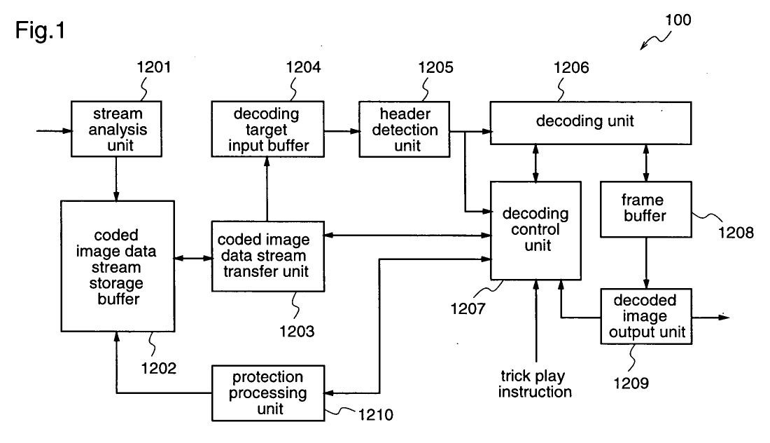

FIG. 1 is a block diagram illustrating an example of the construction of the video reproduction apparatus 100 according to the first embodiment of the present invention.

In FIG. 1, the video reproduction apparatus 100 according to the first embodiment comprises a stream analysis unit 1201, a coded image data stream storage buffer 1202, a coded image data stream transfer unit 1203, a decoding target input buffer 1204, a header detection unit 1205, a decoding unit 1206, a decoding control unit 1207, a frame buffer 1208, a decoded image output unit 1209, and a protective processing unit 1210. The respective constituents perform processes as follows.

The stream analysis unit 1201 analyzes a stream that is read from a DVD (Digital Versatile Disk), an HDD (Hard Disk Drive) or the like, and stores a coded image data stream in the coded image data stream storage buffer 1202.

The coded image data stream storage buffer 1202 is a buffer region in which the coded image data stream analyzed by the stream analysis unit 1201 is stored.

The coded image data stream transfer unit 1203 transfers the coded image data stream from the coded image data stream storage buffer 1202 to the decoding target input buffer 1204. When the coded image data stream transfer unit 1203 receives, from the decoding control unit 1207, a request for retransfer of coded image data stream, the transfer unit 1203 returns a pointer indicating the read position of coded image data to be transferred, to a protective position in which the last-time transferred coded image data is not overwritten, and performs transfer processing.

The decoding target input buffer 1204 is a buffer region in which the coded image data stream transferred from the coded image data stream transfer unit 1203 is stored.

The header detection unit 1205 reads the coded image data stream on the decoding target input buffer 1204, detects a picture header position, and outputs the stream to the decoding unit 1206 and the decoding control unit 1207.

The decoding unit 1206 decodes the inputted coded image data stream, and stores the decoded image data stream into the frame buffer 1208. The decoding unit 1206 comprises a variable length decoder VLD, an inverse quantizer IQ, an inverse discrete cosine transform unit IDCT, and a motion compensation unit MC.

The decoding control unit 1207 controls the decoding process of the decoding unit 1206, and performs output setting to the decoded image output unit 1209, on the basis of the header information supplied from the header detection unit 1205. Further, the decoding control unit 1207 receives a trick play instruction, and controls the decoding unit 1206 and the decoded image output unit 1206.

Further, when decoding of an inter-frame bidirectional predictive coded image is performed, the decoding control unit 1207 judges that an already-output decoded image data region, which is informed from the decoded image output unit 1209, is writable, and notifies the decoding unit 1206 of this information. Further, in order to enable retransfer of inter-frame bidirectional predictive coded image data, the decoding control unit 1207 notifies the coded image data stream transfer unit 1203 and the protective processing unit 1210 of the header position of the coded image data stream stored in the decoding target input buffer, which is detected by the header detection unit 1205, the request for retransfer of the coded image data stream, and the updation of the protective position.

Furthermore, the decoding control unit 1207 judges whether retransfer of the coded image data should be performed or not, on the basis of the coding prediction direction of the coded image data, the header information that is added to the coded image data or to the coded image data stream, and the contents and timing of the trick play instruction.

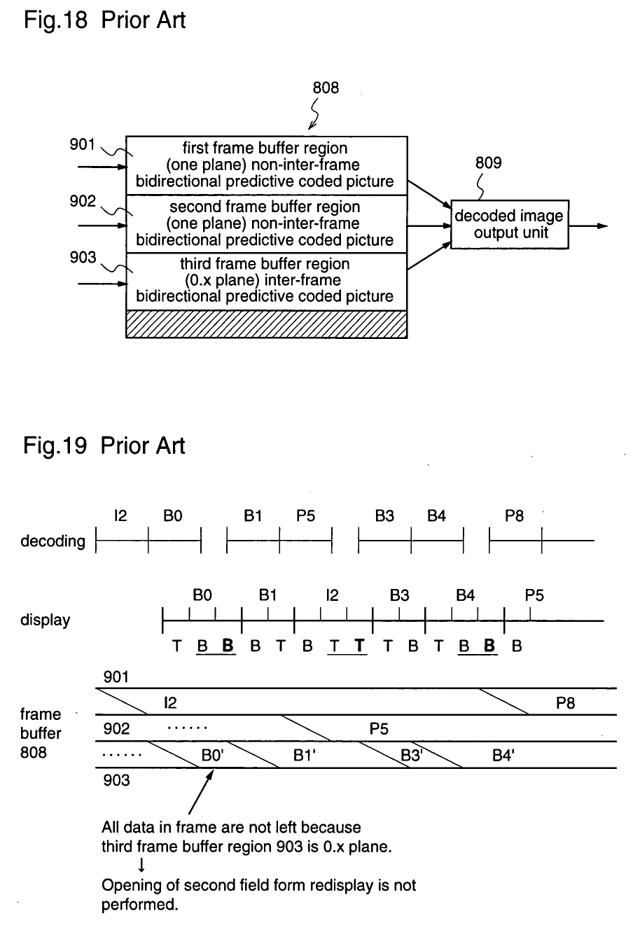

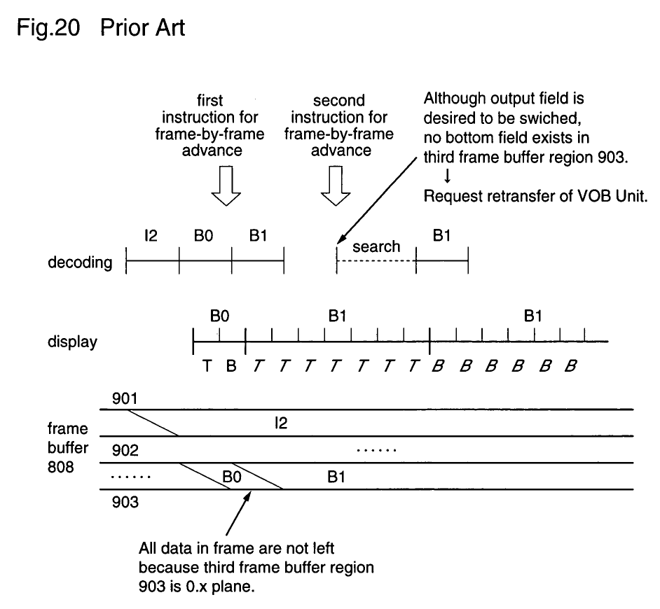

The frame buffer 1208 is a buffer region wherein the decoded image data stream obtained by the decoding unit 1206 is stored, and a frame buffer region for inter-frame bidirectional predictive coded pictures is less than one plane. Since the structure of the frame buffer 1208 is identical to that of the frame buffer 808 shown in FIG. 18, repeated description is not necessary. In the frame buffer 1208 of the video reproduction apparatus according to the first embodiment, for example, the third frame buffer region for inter-frame bidirectional predictive coded pictures is 0.7 plane.

The decoded image output unit 1209 displays the decoded image data stream stored in the frame buffer 1208, according to the output setting that is set by the decoding control unit 1207. Further, in order to reproduce the video data using the frame buffer having only a region less than one plane for inter-frame bidirectional predictive coded pictures, the decoded image output unit 1209 notifies the decoding control unit 1207 of the already outputted decoded image data region on the third frame buffer region for inter-frame bidirectional predictive coded pictures, when decoding of the inter-frame bidirectional predictive coded pictures is performed.

The protection processing unit 1210 prevents the data that is likely to be retransferred from being overwritten by the stream analysis unit 1201, in the coded image data stream storage buffer 1202. When the decoding control unit 1207 notifies the protective processing unit 1210 of the header position of the coded image data stream stored in the decoding target input buffer 1204, which header position is detected by the header detection unit 1205, the protective processing unit 1210 calculates a header position on the coded image data stream storage buffer 1202, and brings the protective position to the calculated position when there is no next retransfer request. Further, the protective processing unit 1210 determines as to whether the coded image data on the coded image data stream storage buffer 1202 should be protected or not, on the basis of the coding prediction direction of the coded image data.

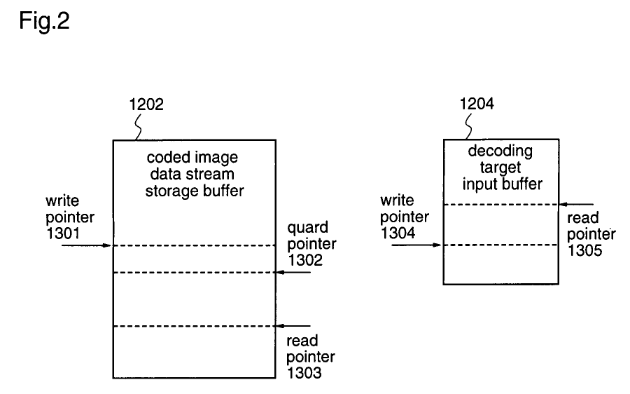

FIG. 2 is a diagram illustrating pointers of the coded image data stream storage buffer 1202 and the decoding target input buffer 1204, in the video reproduction apparatus 100 according to the first embodiment.

With reference to FIG. 2, the coded image data stream storage buffer 1202 has a write pointer 1301 that is used for writing by the stream analysis unit 1201, a guard pointer 1302 that is controlled by the protection processing unit 1210, and a read pointer 1303 that is used for reading by the coded image data stream transfer unit 1203. The decoding target buffer 1204 has a write pointer 1304 that is used for writing by the coded image data stream transfer unit 1203, and a read pointer 1305 that is used for reading by the header detection unit 1205.

The stream analysis unit 1201 writes the coded image data stream that is obtained by analysis, in the position of the write pointer 1301 of the coded image data stream storage buffer 1202.

The coded image data stream transfer unit 1203 reads the data from the position of the read pointer of the coded image data stream storage buffer 1202, and writes the data in the position of the write pointer 1304 of the decoding target input buffer 1204.

In the video reproduction apparatus, the data which is likely to be retransferred is protected so as not to be overwritten by the stream analysis unit 1201, even when the data is read once passing through the position of the read pointer 1303 of the coded image data stream storage buffer 1202 and then written in the position of the write pointer 1304 of the decoding input buffer 1204. So, there is provided a restriction that the write pointer 1301 of the coded image data stream storage buffer 1202 cannot exceed the position of the guard pointer 1302, and the protection processing unit 1210 controls the guard pointer 1302 of the coded image data stream storage buffer 1202 on the basis of the information that is notified from the decoding control unit 1207.

The header detection unit 1205 reads the data from the position of the read pointer 1305 of the decoding target input buffer 1204, and performs header detection.

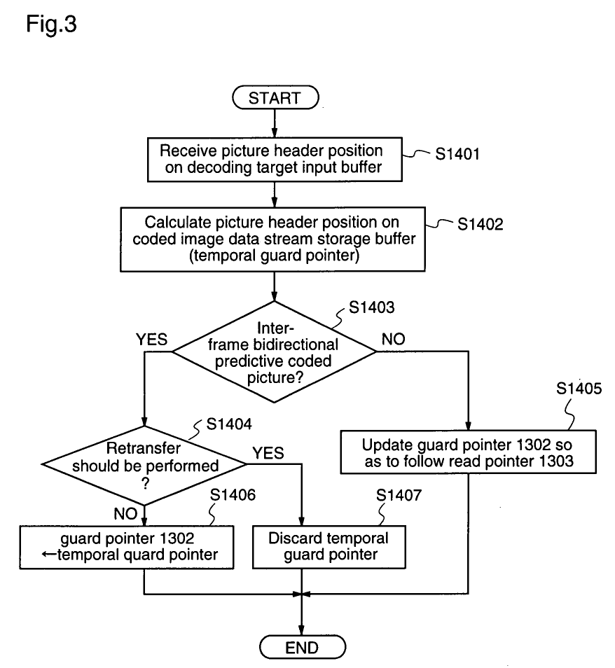

Next, the operation of the video reproduction apparatus 100 for performing the coded image data retransfer process will be described with reference to FIGS. 3 to 9.

The coded image data retransfer process comprises a step of protecting the data on the coded image data stream storage buffer 1202, which data is likely to be retransferred, so as not to be overwritten with new coded image data analyzed by the stream analysis unit 1201, and a step of judging as to whether retransfer is required or not.

The decoding control unit 1207 notifies the protection processing unit 1210 of the picture header position on the decoding target input buffer 1204. The protection processing unit 1210 calculates a picture header position on the coded image data stream storage buffer 1202 on the basis of the information notified from the decoding control unit 1207, and uses the calculated header position as an updated value of the guard pointer 1302. The timing of updation of the guard pointer 1302 varies according to the result of the retransfer judgment process, which is notified by the decoding control unit 1207.

FIG. 3 is a flowchart illustrating the process to be performed by the protection processing unit 1210 in the video reproduction apparatus 100 according to the first embodiment.

The protection processing unit 1210 performs the following process for every frame.

Initially, the protection processing unit 1210 receives the picture header position on the decoding target input buffer 1204, which is notified from the decoding control unit 1207 (step S1401), and calculates a position of a temporal guard pointer, which is a picture header position on the coded image data stream storage buffer 1202 (S1402).

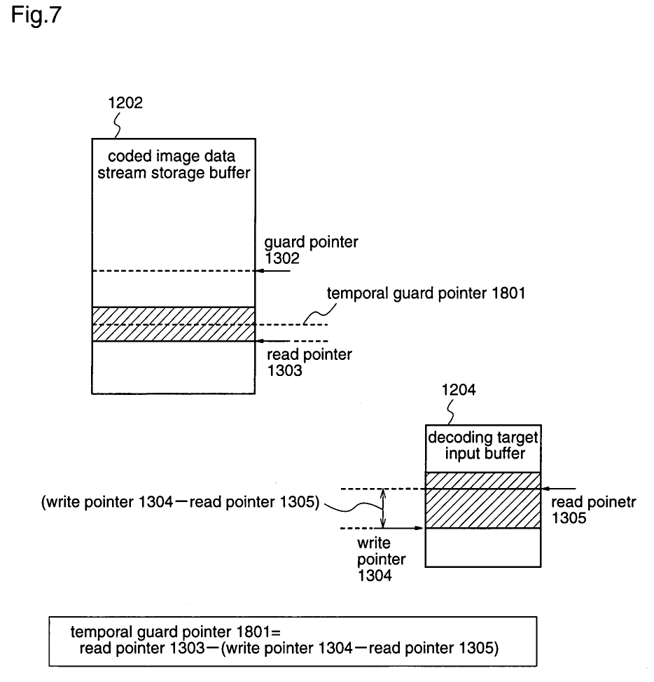

FIG. 7 is a diagram for explaining a method of calculating the position of the temporal guard pointer 1801 which is the picture header position of the data on the coded image data stream storage buffer 120, in the video reproduction apparatus 100 according to the first embodiment.

In FIG. 7, the coded image data stream transfer unit 1203 reads the data from position of the read pointer 1303 of the coded image data stream storage buffer 1202, and writes the data in the position of the write pointer 1304 of the decoding target input buffer 1204, and therefore, in FIG. 7, the data corresponding to the hatched portion of the buffer 1202 is identical to the data corresponding to the hatched portion of the buffer 1204. Accordingly, a position that is obtained by subtracting a difference between the read pointer 1305 on the decoding target input buffer 1204 and the write pointer 1304 on the decoding target input buffer 1204 when the picture header position on the decoding target input buffer 1204 is detected, from the read pointer 1303 on the coded image data stream storage buffer 1202, becomes the position of the temporal guard pointer 1801 which is the position of the picture header on the coded image data stream storage buffer 1202.

Next, as shown in FIG. 3, it is checked whether the decoding target is an inter-frame bidirectional predictive coded picture or not (step S1403).

When the decoding target is an inter-frame bidirectional predictive coded picture (“Yes” in step S1403), a process to be taken next differs depending on a notification from the decoding control unit 1207 as to whether retransfer of data is required or not (step S1404). When retransfer is not required (“No” in step S1404), the guard pointer 1302 of the coded image data stream storage buffer 1202 is updated to the temporal guard pointer 1801 which is the position of the next picture header calculated by the protection processing unit 1210 (step S1406). When retransfer is required (“Yes” in step S1404), the temporal guard pointer 1801 is discarded (step S1407), and the guard pointer 1302 of the coded image data stream storage buffer 1202 is not updated.

When the decoding target is a non-inter-frame bidirectional predictive coded picture (“No” in step S1403), since one plane of frame buffer region for non-inter-frame bidirectional predictive coded pictures exists and therefore retransfer of data is not necessary, the guard pointer 1302 is updated with the read pointer 1303 of the last-time read data (step S1405).

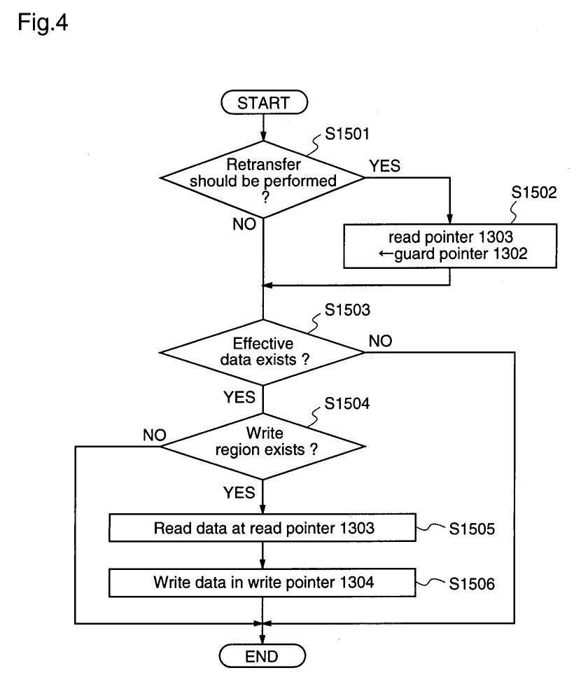

FIG. 4 is a flowchart illustrating the process performed by the coded image data stream transfer unit 1203 in the video reproduction apparatus 100 according to the first embodiment.

The coded image data stream transfer unit 1203 always performs the following process regardless of frames.

Initially, it is checked as to whether there is a notification requesting retransfer of data, from the decoding control unit 1207 (step S1501). When there is a notification requesting retransfer (“Yes” in step S1501), the read pointer 1303 of the coded image data stream storage buffer 1202 is returned to the position indicated by the guard pointer 1302 (step S1502).

Next, when effective data exists on the coded image data stream storage buffer 1202 (“Yes” in step S1503) and a region in which the read data can be written exists on the decoding target input buffer 1204 (“Yes” in step S1504), the data in the position of the read pointer 1303 of the coded image data stream storage buffer 1202 (the same data as the last-time transferred data) is read out (step S1505), and the data is written in the position of the write pointer 1304 of the decoding target input buffer 1204 (step S1506).

Further, in the case where there is no notification requesting retransfer of data from the decoding control unit 1207 (“No” in step S1501), when effective data exists on the coded image data stream storage buffer 1202 (“Yes” in step S1503) and a region where the read data can be written exists in the decoding target input buffer 1204 (“Yes” in step S1504), the data in the position indicated by the read pointer 1303 of the coded image data stream storage buffer 1202 (the data next to the last-time transferred data) is read out (step S1505), and the data is written in the position of the write pointer 1304 of the decoding target input buffer 1204 (step S1506).

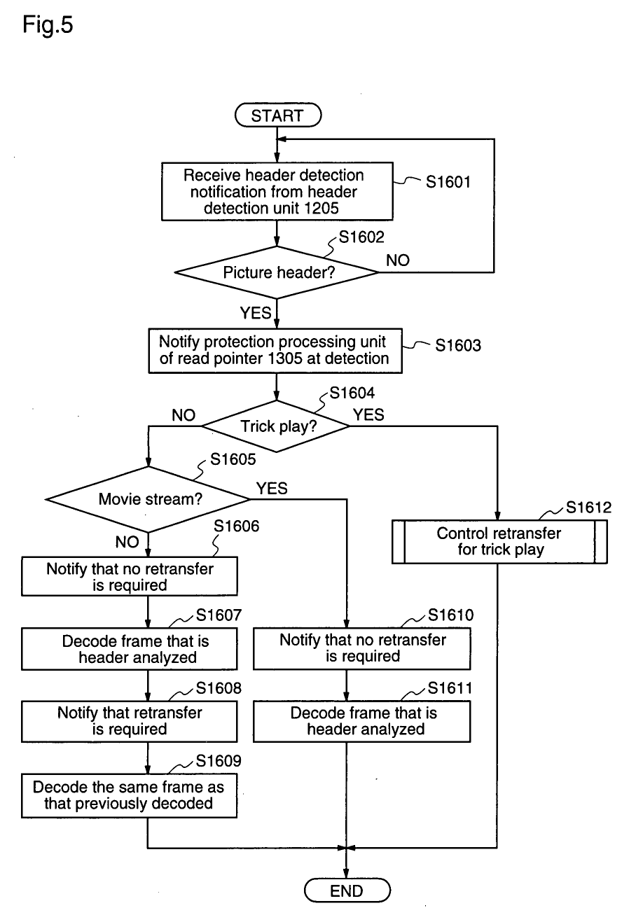

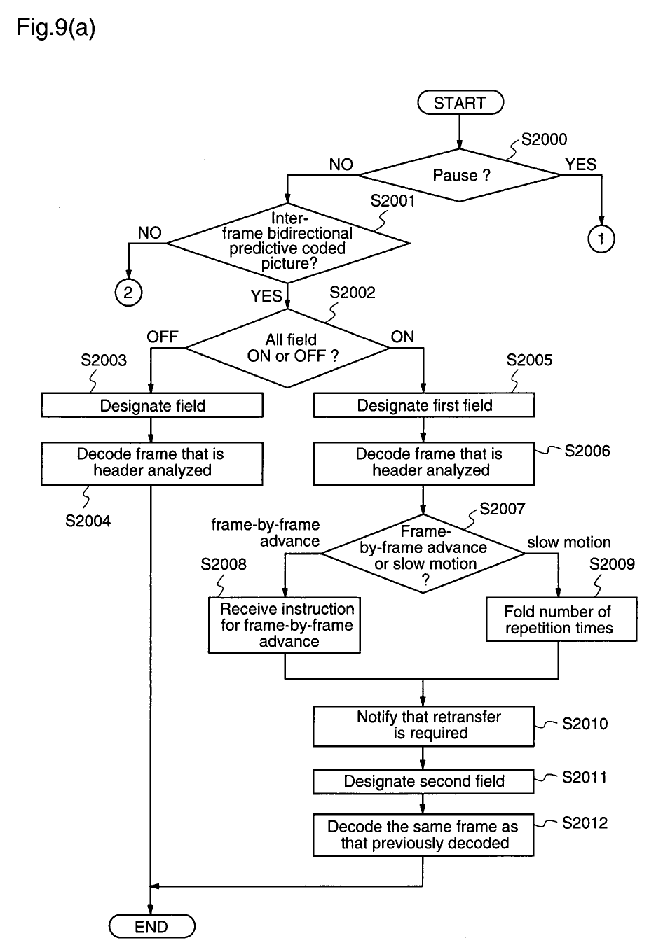

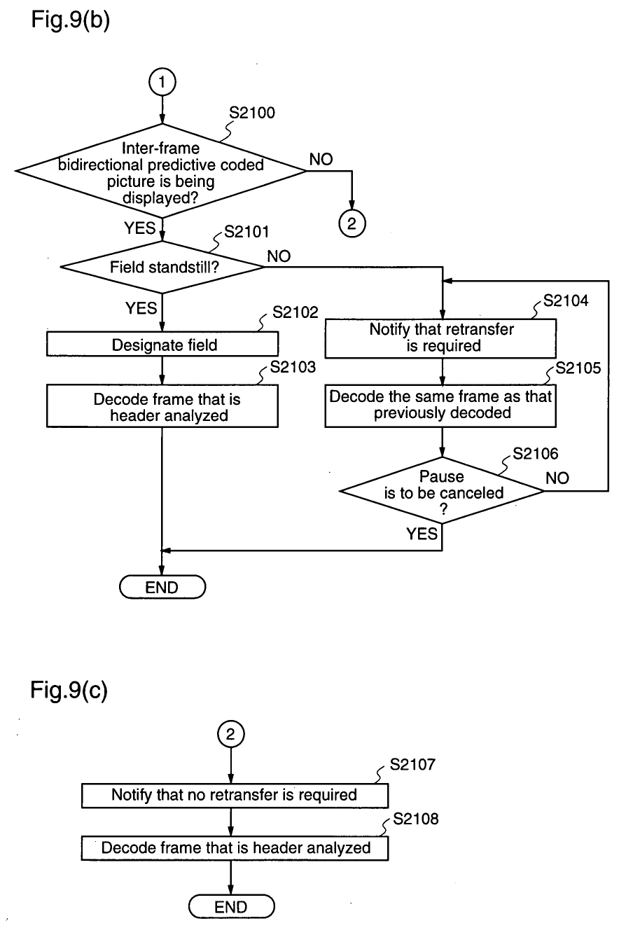

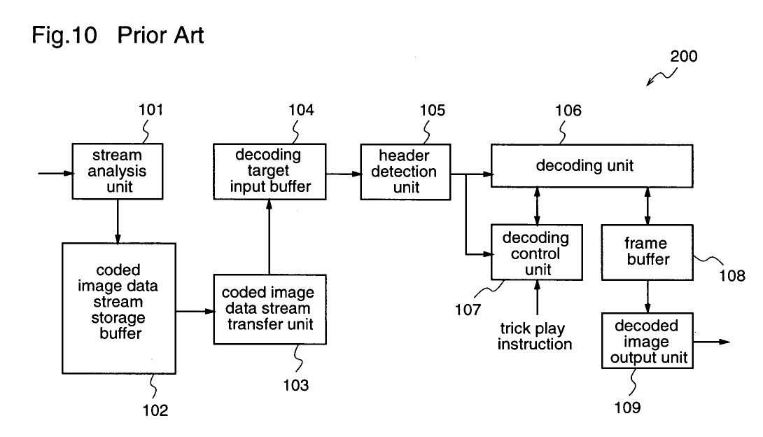

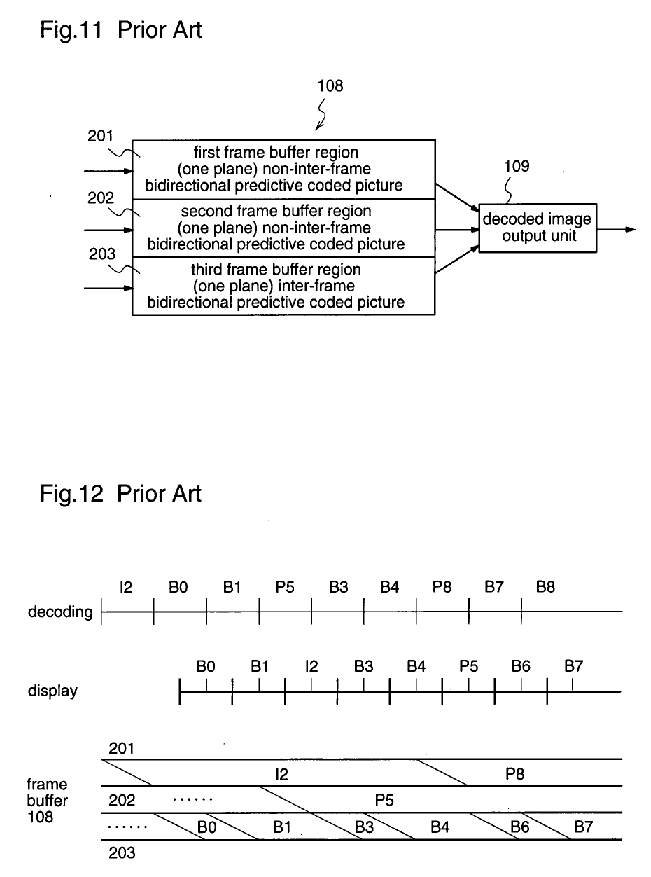

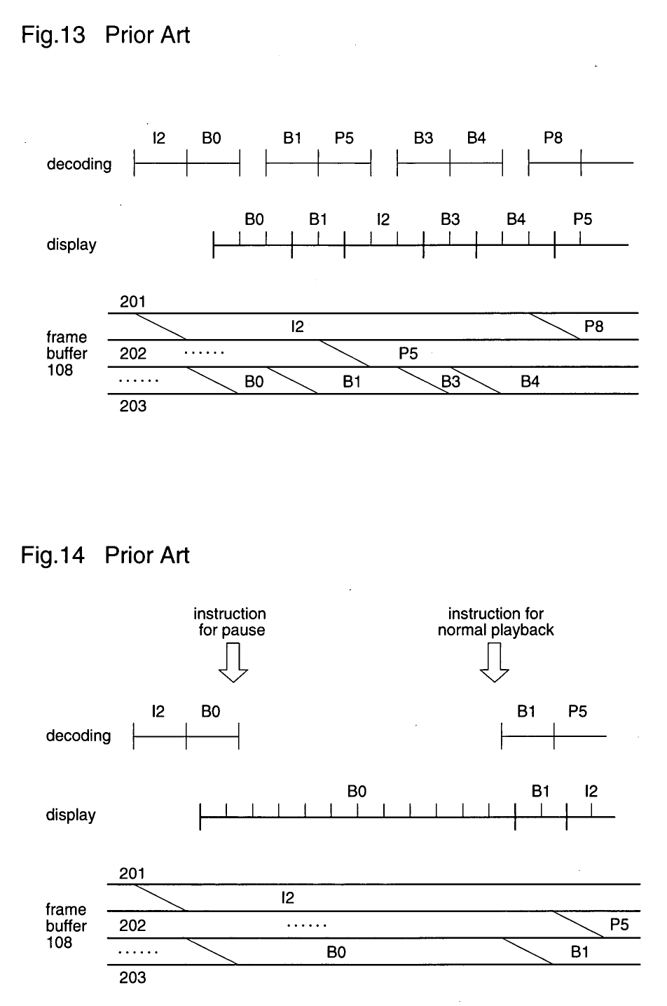

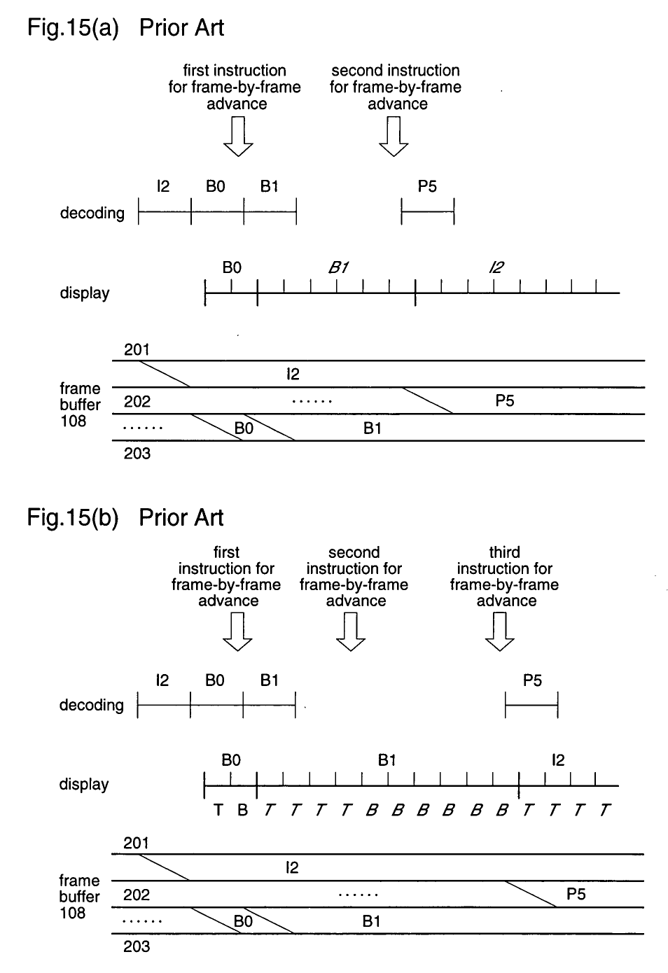

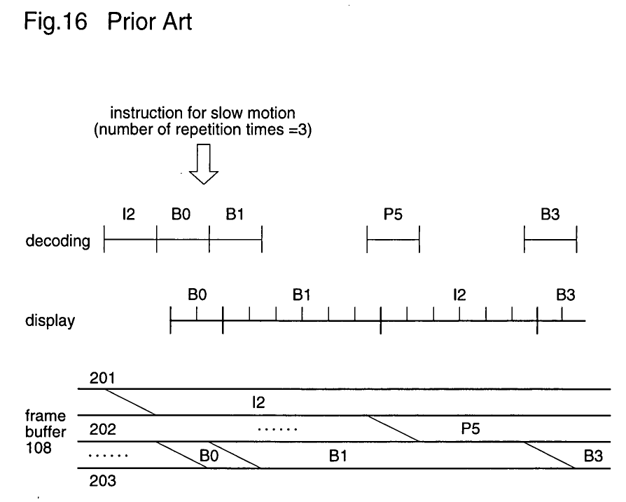

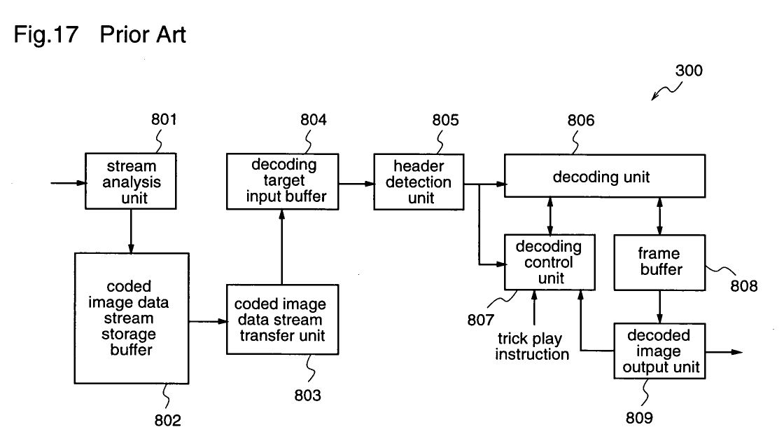

FIGS. 5 and 9 are flowcharts illustrating the processes to be performed by the decoding control unit 1207 in the video reproduction apparatus 100 according to the first embodiment.

The decoding control unit 1207 performs the following processes for each frame.

With reference to FIG. 5, initially, every time the header detection unit 1205 detects a header, the decoding control unit 1207 checks as to whether the detected header is a picture header or not (steps S1601 and S1602). When the detected header is other than a picture header, the decoding control unit 1207 waits for next header detection (“No” in step S1602). When a picture header is detected (“Yes” in step S1602), the decoding control unit 1207 notifies the protection processing unit 1210 of the read pointer 1305 of the decoding target input buffer 1204 at the timing of the picture header detection (step S1603).

Next, it is checked as to whether trick play is requested or not (step S1604).

When no trick play is requested (“No” in step S1604), i.e., when normal playback is requested, it is checked whether the decoding target is a movie material stream or not (step S1605).

When it is a movie material stream (“Yes” in step S1605), initially it is notified that no retransfer is required (step S1606), and the coded image data that is currently subjected to header analysis is decoded (step S1607). Thereafter, it is immediately notified that retransfer should be performed (step S1608), and retransfer of the coded image data that has just been decoded in step S1607 is requested, and decoding of the same coded image data is again performed (step S1609). The notification as to whether retransfer should be performed or not is received by the protection processing unit 1210, and as described for FIG. 3, the protection processing unit 1210 performs discarding of the temporal guard pointer upon receipt of the notification requesting retransfer, while it performs updation of the guard pointer 1302 upon receipt of the notification requesting no retransfer.

The reason why the movie material stream is processed in the above-mentioned flow is because even a video reproduction apparatus using a relatively low performance decoding unit can realize three-field output.

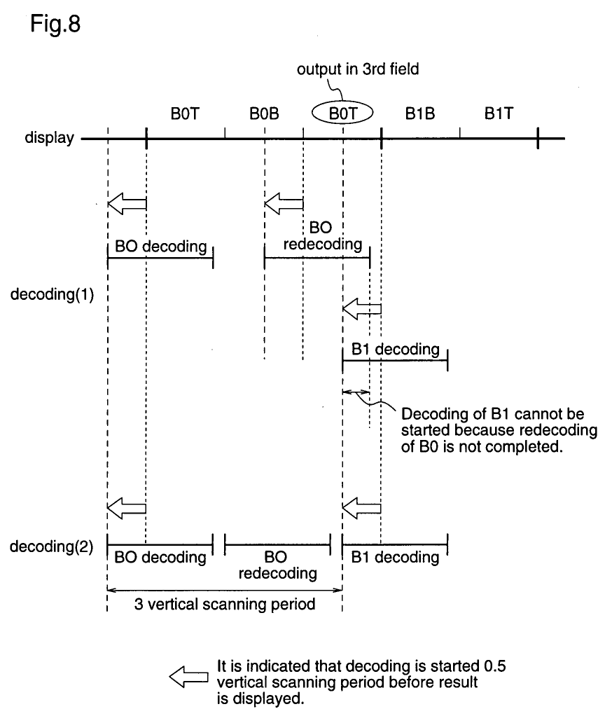

FIG. 8 is a timing chart illustrating the relationship between the decoding process and the display process for the movie material stream, in the video reproduction apparatus 100 according to the first embodiment. In FIG. 8, the decoding process requires 1.3 vertical scanning period for processing one frame.

With reference to FIG. 8, 3-field output generates output data in the third field by retransfer. Usually, the decoding process is started 0.5 vertical scanning period before the result display. Therefore, in the decoding process for the final third field, if decoding of one frame cannot be completed within one vertical scanning period, when a B0 picture is decoded and then the B0 picture is redecoded, the redecoding of the B0 picture is not completed as shown by “decoding (1)” in FIG. 8, and therefore decoding of a B1 picture for the next output cannot be started. So, with reference to the process flow from step S1607 to step S1610 shown in FIG. 5, as shown by “decoding (2)” in FIG. 8, decoding of two frames, i.e., decoding of the B0 picture and redecoding of the B0 picture, are performed within three vertical scanning period. When using a decoding unit having a performance that requires 1.3 vertical scanning period for processing one frame, since decoding of the first frame is completed by 1.5 vertical scanning period, retransfer is performed immediately after the decoding and redecoding is carried out, whereby decoding for the two frames can be completed before three vertical scanning period has passed. Thus, three-field output is realized in the video reproduction apparatus using a relatively low performance decoding unit.

Further, when the decoding target is not a movie material stream as shown in FIG. 5 (“No” in step S1605), since retransfer of data is not necessary, the process goes to decoding of the frame that is currently subjected to header analysis. Initially, it is notified that retransfer is not required (step S1610), and the frame that is currently subjected to header analysis is decoded (step S1611).

Next, when it is judged that trick play is required as shown in FIG. 5 (“Yes” in step S1604), retransfer control for trick play is performed (step S1612).

Hereinafter, data retransfer control for trick play will be described with reference to FIGS. 9(a) to 9(c).

FIG. 9(a) shows a case where an inter-frame bidirectional predictive coded picture is processed without performing pause in trick play, FIG. 9(b) shows a case where pause is performed in trick play, and figure (c) shows a case where a non-inter-frame bidirectional predictive coded picture is processed without performing pause in trick play.

In FIG. 9(a), when performing trick play, it is initially judged whether the trick play is pause or not (step S2000).

When it is not pause (“No” in step S2000), i.e., when it is frame-by-frame advance or slow motion, detection of a picture header is terminated, and then it is checked whether a coded picture to be decoded now (decoding target) is an inter-frame bidirectional predictive coded picture or not (step S2001).

When the decoding target is not an inter-frame bidirectional predictive coded picture (“No” in step S2001), since retransfer is not necessary, the process goes to decoding of the frame that is currently subjected to header analysis. As shown in FIG. 9(c), it is notified that retransfer is not required (step S2107), and the frame that is currently subjected to header analysis is decoded (step S2108).

When the decoding target is an inter-frame bidirectional predictive coded picture (“Yes” in step S2001), it is further checked as to whether trick play should be performed using all fields or not (all field ON/OFF setting) (step S2002).

When “all field OFF” is set in step S2002, since only one field will be repeatedly output, the field to be repeatedly output is designated (step S2003), and the frame that is currently subjected to header analysis is decoded (step S2004). When “all field ON” is set in step S2002, since trick play is performed using the both fields, initially the first field is designated (step S2005), and the frame that is currently subjected to header analysis is decoded (step S2006) and outputted.

Next, it is judged whether the trick play is frame-by-frame advance or slow motion (step S2007). When it is frame-by-frame advance, the output field is switched to the second field of the same inter-frame bidirectional predictive coded picture when a frame-by-frame advance playback instruction is again accepted (step S2008). When it is slow motion, the output field is switched to the second field of the same inter-frame bidirectional predictive coded picture when display corresponding to the half of the number of repetitive display times is completed (step S2009). At this time, it is notified that retransfer should be performed (step S2010), the second field is designated (step S2011), the field to be left on the frame buffer is changed from the first field to the second field, and the same frame as the last-time decoded frame is decoded (step S2012).

In the video reproduction apparatus 100 according to the first embodiment, while the third frame buffer region 903 for inter-frame bidirectional predictive coded pictures is 0.7 plane, when “all field OFF” is set in step S2002 and only the field data of either the top field or the bottom field (corresponding to 0.5 plane) is repeatedly output, decoding for one field designated is carried out, whereby only the designated field data is decoded, and retransfer of useless coded image data is avoided. Further, in the decoding for the one field designated, only the field data of the designated one field is written in the third frame buffer region 903 for inter-frame bidirectional predictive coded pictures, and the region is not opened even after outputting, whereby repetitive outputting of the field data can be performed because the filed data remains in the third frame buffer region 903. Furthermore, the other field data that is not designated is written in an ineffective region that is called a dummy region, and the decoding result thereof is discarded.

Next, in FIG. 9(a), when the trick play is pause (“Yes” in step S2000), initially, it is checked whether the decoded data that is currently outputted is an inter-frame bidirectional predictive coded picture or not, as shown in FIG. 9(b) (step S2100).

When the decoded data is not an inter-frame bidirectional predictive coded picture (“No” in step S2100), since retransfer is not necessary, the process goes to decoding of the frame that is currently subjected to header analysis. As shown in figure 9(c), it is notified that retransfer is not required (step S2107), and the frame that is currently subjected to header analysis is decoded (step S2108).

When the decoded data is an inter-frame bidirectional predictive coded picture (“Yes” in step S2100), it is further checked whether it is field freeze or not (step S2101). When it is field freeze (“Yes” in step S2101), since only one field will be repeatedly output, the field to be repeatedly output is designated (step S2102), and the frame that is currently subjected to header analysis is decoded (step S2103). When it is not field freeze (“No” in step S2102), that is, when it is frame freeze, since the decoded data of the both fields are required for every two vertical scanning period, it is notified that retransfer should be performed (step S2104), and the same frame as the last-time decoded frame is continuously decoded (step S2105) until the pause instruction is cancelled (“No” in step S2106).

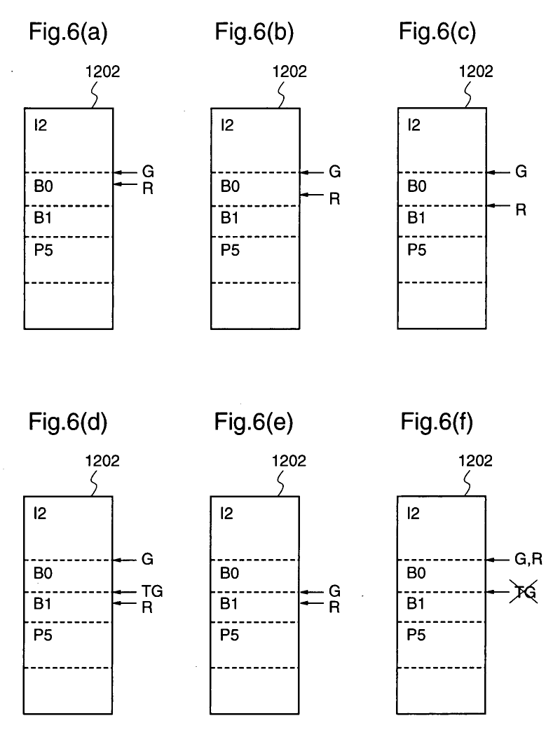

FIGS. 6(a) to 6(f) are diagram illustrating transitions of pointers during video reproduction oh the coded image data stream storage buffer 1202 in the video reproduction apparatus 100 according to the first embodiment. In FIGS. 6(a)-6(f), G denotes a guard pointer 1302, R denotes a read pointer 1303, and TG denotes a temporal guard pointer.

It is assumed that an 12 picture, a B0 picture, a B1 picture, and a P5 picture are sequentially written in the coded image data stream storage buffer 1202 from the top of the buffer 1202 as shown in FIGS. 6(a)-6(f). However, the coded image data stream transfer unit 1203 cannot judge the positions where the respective data are stored in the coded image data stream storage buffer 1202.

Hereinafter, transitions of the respective pointers will be described with reference to FIGS. 6(a)-6(f). Depending on whether retransfer of data should be performed or not, the pointers transit in order of (a)→(b)→(c)→(d)→(e) or (f).

First of all, as shown by the transition from FIG. 6(a) to 6(b), while the coded data of the P0 picture that is pointed by the read pointer (R) 1303 of the coded image data stream storage buffer 1202 is being read, the temporal guard pointer (G) 1302 continues to point the head of the B0 picture.

As reading of the data at the position pointed by the read pointer 1303 is further continued, the read pointer 1303 becomes to point the data at the head of the B1 picture as shown in FIG. 6(c). At this time, the header data of the B1 picture is transferred from the coded image data stream storage buffer 1202 to the decoding target input buffer 1204 by the coded image data stream transfer unit 1203. Then, on receipt of the result of header detection by the header detection unit 1205, the decoding control unit 1207 notifies the protection processing unit 1210 of the head position of the B1 picture on the decoding target input buffer 1204.

As shown in FIG. 6(d), the protection processing unit 1210 calculates a position of the temporal guard pointer (TG) at the head position of the B1 picture on the coded image data stream storage buffer 1202, on the basis of the information notified from the decoding control unit 1207. Thereafter, when the decoding control unit 1207 notifies that retransfer of data is not required, since retransfer of the B0 picture is not carried out, i.e., since it is not necessary to protect the B0 picture so as not to be overwritten, the guard pointer 1302 is updated with the temporal guard pointer (the head position of the next B1 picture) as shown in FIG. 6(e).

On the other hand, when the decoding control unit 1207 notifies that retransfer of data is required, in order to perform retransfer of the B0 picture, the read pointer 1303 is updated with the guard pointer 1302 (the head position of the B0 picture) so as to prevent the B0 picture from being overwritten as shown in FIG. 6(f), and the temporal guard pointer that is calculated in FIG. 6(d) is discarded because updation of the guard pointer 1302 becomes unnecessary.

Further, as described above, calculation of the position of the temporal guard pointer on the coded image data stream storage buffer 1202 and updation of the guard pointer 1302 or the read pointer 1303 are performed when the head position of the next frame is detected.

Therefore, when the data size of the inter-frame bidirectional predictive coded picture is too large to be stored in the coded image data stream storage buffer 1202, that is, when the write pointer 1301 used by the stream analysis unit 1210 for writing, which is moved and wrapped around with the writing process in the coded image data stream storage buffer 1202, overlaps the guard pointer 1302 used by the protection processing unit 1210 for protection of data from being overwritten, there is a possibility that coded image data sufficient to complete the decoding process cannot be stored in the coded image data stream storage buffer 1202.

Accordingly, for example, when the write pointer 1301 comes close to the guard pointer 1302 exceeding a predetermined limit, the guard pointer 1302 is updated to the position of the read pointer 1303 (the head position of the next picture) so as to cancel the protection for preventing the coded image data from being overwritten. Then, the data of the next picture is transferred from the coded image data stream storage buffer 1202 to the decoding target input buffer 1204, and further, a new coded image data stream outputted from the stream analysis unit 1201 is stored in the coded image data stream storage buffer 1202.

At this time, since the data in the coded image data stream storage buffer 1202 is not protected by the guard pointer 1302 so as not to be overwritten, retransfer of the already transferred data cannot be performed. However, it is possible to prevent the operation of the video reproduction apparatus from being stopped, which is caused by that coded data sufficient to complete the decoding process is not stored. Further, even when the coded image data exceeds the supposed size, since the protection for preventing the coded image data from being overwritten is canceled, and the next picture data is transferred from the coded image data stream storage buffer 1202 to the decoding target input buffer 1204, and then a new coded image data stream outputted from the stream analysis unit 1201 is stored in the coded image data stream storage buffer 1202, it is possible to continue the reproduction process although the image is momentarily disordered.

Even when it is judged that retransfer of the coded image data should be performed in the video reproduction apparatus 100 of the first embodiment, if the image size to be outputted is small and the decoded image data to be redisplayed remains on the frame buffer, the decoding control unit 1207 may perform control so as not to carry out retransfer of the coded image data.

As described above, according to the present invention, in the video reproduction apparatus that reproduces video data using the frame buffer 1208 having only a region less than one plane for inter-frame bidirectional predictive coded pictures, when repetitive display of inter-frame bidirectional predictive coded image data is required, the same coded image data as the coded image data that has been once transferred from the coded image data stream storage buffer 1202 is again transferred, and the same coded image data as the coded image data that has previously been decoded is again decoded and outputted, whereby decoding is continuously carried out, resulting in realtime repetitive display having no distortion of image display, and requiring no waiting time.

### APPLICABILITY IN INDUSTRY

A video reproduction apparatus according to the present invention is applicable to a video decoding technique and a video reproduction technique which realize realtime repetitive reproduction and display having no distortion of image display and requiring no waiting time, when repeatedly displaying an inter-frame bidirectional predictive coded picture using a frame buffer having only a region less than one plane for inter-frame bidirectional predictive coded pictures.

What is claims is:

1. A video reproduction apparatus for reproducing video data, including a frame buffer having a region less than one plane for storing inter-frame bidirectional predictive coded pictures, said apparatus comprising:
a header detection unit for detecting a header position of a coded image data stream that is stored in a decoding target input buffer;
a decoding control unit for controlling a decoding process on the basis of header information supplied from the header detection unit, to which a reproduction instruction for performing repetitive display of the same decoded image data is inputted from the outside;
a protection processing unit for calculating a position of the coded image data stream on the coded image data stream storage buffer, on the basis of the position of the coded image data stream on the decoding target input buffer, which is supplied from the decoding control unit, and protecting the position of the coded image data stream so as not to be overwritten with a coded image data stream different from the coded image data stream; and
a coded image data stream transfer unit for, when there is a request from the decoding control unit for retransferring the coded image data stream, performing retransfer of the coded image data stream on the basis of the position of the coded image data stream on the decoding target input buffer.

2. A video reproduction apparatus as defined in claim 1 wherein said protection processing unit determines as to whether the coded image data on the coded image data stream storage buffer should be protected or not, on the basis of a coding prediction direction of the coded image data.

3. A video reproduction apparatus as defined in claim 1 wherein said decoding control unit judges as to whether retransfer of the coded image data should be performed or not, on the basis of the coding prediction direction of the coded image data, and header information that is added to the coded image data or the coded image data stream.

4. A video reproduction apparatus as defined in claim 1 wherein said decoding control unit judges as to whether retransfer of the coded image data should be performed or not, on the basis of the coding prediction direction of the coded image data, and a trick play instruction.

5. A video reproduction apparatus as defined in claim 3 wherein, even when the decoding control unit determines that retransfer of the coded image data should be performed, retransfer of the coded image data is not carried out if the size of video image to be outputted is small and decoded image data to be redisplayed remains on the frame buffer.

6. A video reproduction apparatus as defined in claim 4 wherein, even when the decoding control unit determines that retransfer of the coded image data should be performed, retransfer of the coded image data is not carried out if the size of video image to be outputted is small and decoded image data to be redisplayed remains on the frame buffer.

7. A video reproduction apparatus as defined in claim 1 wherein, when coded image data for decoding cannot be stored in the coded image data stream storage buffer, the protection processing unit does not perform protection for preventing the last-time coded image data from being overwritten, and the coded image data transfer unit transfers the coded image data next to the last-time transferred data on the coded image data stream storage buffer, to the decoding target input buffer.
